(19) United States
(12) Patent Application Publication
(10) Pub. No.: US 2024/0240323 A1
(43) Pub. Date: Jul. 18, 2024

(54) VALVE PULSING TO CONTROL PRECURSOR PRESSURE

(71) Applicant: ASM IP Holding B.V., Almere (NL)

(72) Inventors: Ryan Paull, Gilbert, AZ (US); Andrew O'Reilly, Chandler, AZ (US); Ashwin Agathya Boochakravarthy, Fremont, CA (US); Jereld Lee Winkler, Gilbert, AZ (US); Chen Ni, Phoenix, AZ (US); Gnyanesh Trivedi, Tempe, AZ (US)

(21) Appl. No.: 18/411,900

(22) Filed: Jan. 12, 2024

Related U.S. Application Data
(60) Provisional application No. 63/480,204, filed on Jan. 17, 2023.

(51) Int. Cl. C23C 16/52; C23C 16/455; F16K 7/00; G05D 16/20

(52) U.S. Cl. CPC C23C 16/52; C23C 16/45544; C23C 16/45557; F16K 7/00; G05D 16/2013

(57) ABSTRACT

A reactor system configured to use valve pulsing to control precursor pressure as part of substrate or other processing. A controller in the reactor system runs a pressure control module to process pressure signals from a pressure sensor sensing pressure within an accumulator disposed between a reaction chamber and a precursor source vessel. Based on a pressure set point for the accumulator and the sensed pressure feedback, the controller generates valve control or valve pulsing signals to operate one or more fill valves used to control fill of the accumulator with gas (e.g., precursor) from the precursor source vessel. The fill valves may be high-speed diaphragm valves configured for operation in high temperature applications to be fully opened or fully closed, and the control signals cause the valves to rapidly pulse open and closed to adjust the pressure within the accumulator.

### CROSS-REFERENCE TO RELATED APPLICATIONS

This application is a nonprovisional of, and claims priority to and the benefit of, U.S. Provisional Patent Application No. 63/480,204, filed Jan. 17, 2023 and entitled “VALVE PULSING TO CONTROL PRECURSOR PRESSURE,” which is hereby incorporated by reference herein.

### FIELD OF THE DISCLOSURE

The present disclosure generally relates to reactor systems used, for example, in manufacture of semiconductor wafers including gas-phase reactors and systems. More particularly, the disclosure relates to a method, and systems for implementing the method, for providing improved pressure control within an accumulator used to feed precursors to one or more reaction or processing chambers during substrate or wafer processing that is particularly suited for high temperature applications.

### BACKGROUND OF THE DISCLOSURE

Gas-phase reactors, such as chemical vapor deposition (CVD), plasma-enhanced CVD (PECVD), and atomic layer deposition (ALD) reactors can be used for a variety of applications, including depositing and etching materials on a substrate surface (e.g., semiconductor wafer). For example, gas-phase reactors can be used to deposit and/or etch layers on a substrate to form semiconductor devices, flat panel display devices, photovoltaic devices, microelectromechanical systems (MEMS), and the like.

A typical gas-phase reactor system includes a reactor including a reaction chamber, one or more precursor and/or reactant gas sources fluidly coupled to the reaction chamber, one or more carrier and/or purge gas sources fluidly coupled to the reaction chamber, a gas injection system to deliver gases (e.g., precursor/reactant gas(es) and/or carrier/purge gas(es)) to the reaction chamber, and an exhaust source fluidly coupled to the reaction chamber. During processing, one or more substrates are placed within the reaction chamber using a substrate transfer device (e.g., linkage or robotic arm). Once placed in the reaction chamber, the substrate(s) may be exposed to various precursors and/or reactant gases. After processing, the substrate(s) are removed from the reaction chamber using the transfer device.

During processing or operations of the reactor system, it is often important to accurately control pressures within the reaction chamber. To this end, many reactor systems include an accumulator, which is provided downstream of a gas source vessel (e.g., a precursor vessel) and is used to provide doses of gas to the reaction chamber. By accurately controlling the pressure within the accumulator, the quantity or dose of precursor provided to the reaction chamber, e.g., during each pulsing dose of substrate processing, is also accurately measurable and controllable as the pressure differential between the reaction chamber and the accumulator drives or controls the flow to the reaction chamber from the accumulator.

In thermal ALD and other processing during reactor system operations, the precursor dose is a function of the pulse time, the flow, and the accumulator pressure. In some applications, it may be desirable to increase the precursor dose, and this can only be done by increasing the pulse time, the flow, the accumulator pressure, or the precursor concentration. However, it is also desirable to maintain or increase throughput. Hence, it may be undesirable to increase the pulse time as this decreases the throughput. When using liquid or solid precursors, the flow is increased through increase of the inert flow, but this dilutes the precursor concentration producing an effect that is opposite of that desired. In order to increase the accumulator pressure, a small accumulator could be used, but this results in a decrease in flow. Hence, none of these approaches has been widely adopted in the semiconductor industry.

To measure dose consumption and control accumulator pressure, it may seem that use of a pressure controller would be a straightforward approach. Consistent accumulator pressure is important since pulse-to-pulse consistency translates to wafer-to-wafer consistency. However, due to high temperature requirements, a heated pressure controller for such applications is not available as existing pressure controllers and associated valving that can be partially opened to meter charging are not suited for use in high-temperature applications including those present in many thermal ALD and other reactor systems proximate to the accumulator and precursor source vessel.

Pressure controllers are useful in some applications to provide consistent accumulator pressure to better ensure pulse-to-pulse consistency that translates into wafer-to-wafer consistency with accurate dose measurement in the reaction chamber. However, due to high temperature requirements, pressure controllers are not presently available for use in many reactor systems. Hence, there remains a demand for a method of controlling accumulator pressure in high temperature applications.

Any discussion, including discussion of problems and solutions, set forth in this section has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various embodiments of the present disclosure are directed to a reactor system configured to use valve pulsing to control precursor pressure as part of substrate or other processing. Particularly, a controller in the reactor system runs a pressure control module to process pressure signals from a pressure sensor operating to sense pressure within an accumulator disposed between a reaction chamber and a precursor source vessel. In response, and based on a pressure set point for the accumulator, the controller generates valve control or valve pulsing signals to operate one or more valves, which are used to control fill of the accumulator with gas (e.g., precursor) from the precursor source vessel. These fill valves preferably take the form of high-speed valves, e.g., diaphragm valves, that are configured for operation in high temperature applications (e.g., precursor gases or other fluids at 100° C. to 250° C. or the like) for full open and full closed operation, and the control signals cause the valves to rapidly pulse open and closed to adjust the pressure within the accumulator to a range of pressures above and below the pressure set point of the accumulator (e.g., switch between open and closed and vice versa over time based on information received from the pressure sensor).

In an arrangement, a method (and corresponding system) is described for controlling precursor pressure in a reactor system. The method includes, in memory or data storage, storing a pressure set point for an accumulator, which is adapted for storing precursor and for discharging the precursor to a reaction chamber during substrate processing. The method also includes, with a pressure sensor, sensing a pressure within the accumulator and, in response, generating a signal indicative of the pressure. Further, the method includes, with a controller, processing the signal from the pressure sensor and the pressure set point. Then, based on the processing, the method includes generating a control signal for a fill valve operable to charge the accumulator with the precursor from a volume of the precursor stored in a precursor source vessel. The control signal causes the fill valve to pulse repeatedly between a closed position and an open position during the substrate processing.

In some implementations of the method, the processing includes a proportional-integral-derivative (PID) control loop taking as input the pressure set point, a user-defined PID parameter, and the signal from the pressure sensor and producing an output. Then, the generating of the control signal may include performing pulse-density modulation (PDM) on the output of the PID control loop. It may be useful in the method to include a step of determining that the accumulator is discharging the precursor to the reaction chamber and, in response, pausing the generating of the control signal for the fill valve.

In some cases, the method is useful for high-temperature applications, and the precursor passing through the fill valve can be at temperatures over 100° C. In such high-temperature applications, the fill valve can be a high-speed valve operable only in a fully open position or a fully closed position, such as is the case with many diaphragm valves. The pulse width may vary to implement the method with some implementations configured such that the control signal causes the fill valve to have a pulse time interval in the range of 1 to 10 milliseconds (ms).

In some cases there is only one fill valve that is controlled to control accumulator pressure, but it may be useful when the precursor has lower volatility for the method to further include, concurrently with the generating the control signal for the fill valve, generating a second control signal for a valve operable to control flow of a carrier gas from a carrier gas source through the precursor source vessel. The control signal causes the fill valve to pulse repeatedly between a closed position and an open position in a pattern matching that of the fill valve operating in response to the control signal.

These and other embodiments will become readily apparent to those skilled in the art from the following detailed description of certain embodiments having reference to the attached figures; the disclosure not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a reactor system configured for valve pulsing for accumulator pressure control.

FIG. 2 illustrates an additional exemplary reactor system configured for valve pulsing for accumulator pressure control.

FIG. 3 is a graph showing results of use of valve pulsing to provide accumulator pressure control.

FIG. 4 illustrates a control flow chart for implementing a valve pulsing pressure control method.

FIG. 5 illustrates a valve pulsing accumulator pressure control method in accordance with the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As used herein, a substrate can refer to any material having a surface onto which material can be deposited. A substrate can include a bulk material such as silicon (e.g., single crystal silicon) or may include one or more layers overlying the bulk material. Further, the substrate may include various topologies formed within or on at least a portion of a layer of the substrate.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

To increase throughput, a shorter pulse time can be utilized and can be compensated for by increasing the accumulator pressure. The accumulator pressure may be increased by charging the accumulator via flow from the accumulator during purge steps, during pulsing steps of other precursors, and, in some cases, during dosing from the accumulator to the reaction chamber. In brief, one or more fill valves of the accumulator are operated or controlled using valve pulsing to switch the valves rapidly (e.g., with pulse intervals in the range of 1 to 7 milliseconds (ms) or longer) between open and closed to simulate partial opening with a high-speed valve that is compatible with and used in high temperature applications (i.e., applications involving fluids such as precursor gases at over 100° C., e.g., in the range of 100 to 250° C., and the like).

To provide increased accumulator pressure, a new control method is described, along with reactor systems configured to implement such a control method. The control method includes pulsing the accumulator fill valve (or valves) to charge the accumulator to a desired pressure setpoint in a substrate processing recipe. A controller runs a pressure control module (e.g., a proportional-integral-derivative (PID) control loop or algorithm) that takes as input or feedback pressure information from an accumulator pressure sensor, and processes the accumulator pressure with the pressure set point for the accumulator and one or more user-defined PID parameters (which may include a pulsing time interval or this may be provided as additional control parameter). Then, applying pulse-density modulation (PDM) the pressure control module operates to generate valve control signals or pulsing signals to operate the fill valve. This may involve use of PDM to convert an analog output to a valve pulse signal (which may be as rapid as ever 1 to 2 ms in some cases) to reach the desired pressure set point. In one arrangement, the controller may take the form of a programmable logic controller (PLC) that is able to run the PID control loop and PDM at a very high cycle time to provide accumulator pressure control in a highly accurate manner.

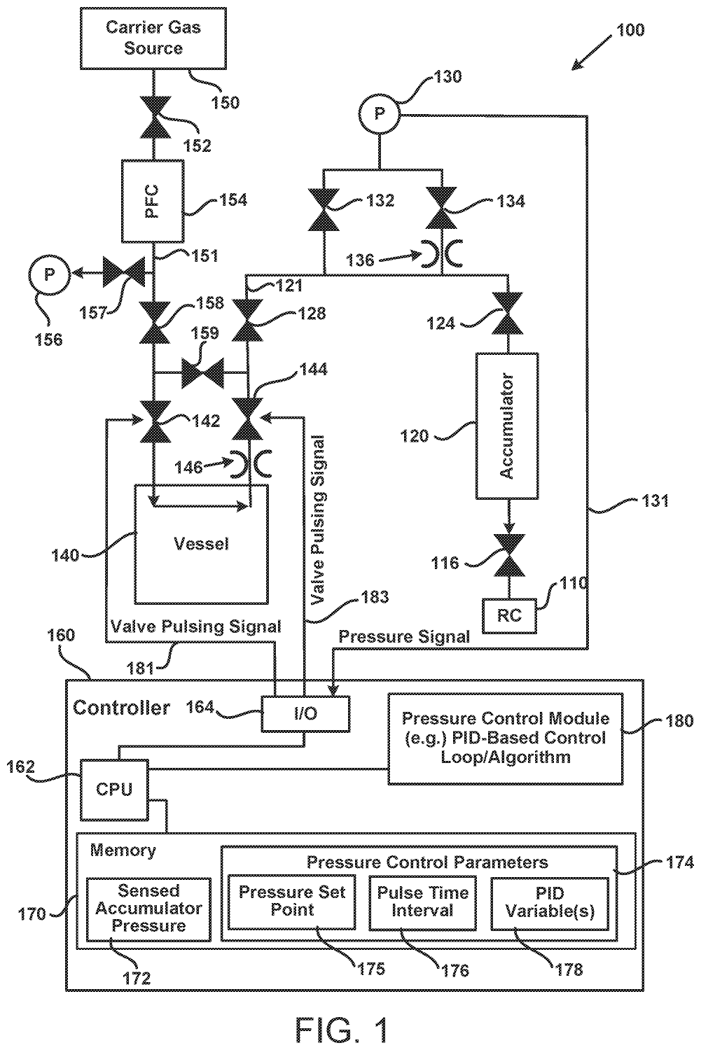

Turning now to the figures, FIG. 1 illustrates an exemplary reactor system 100. The reactor system 100 can be used for a variety of applications, such as, chemical vapor deposition (CVD), plasma-enhanced CVD (PECVD), thermal atomic layer deposition (ALD), clean processes, etch processes, and the like. To this end, the reactor system 100 includes a precursor source vessel 140 (or, more simply, “vessel”) that is used to provide precursor in gas form to an accumulator 120. A valve 116 is disposed between the accumulator 120 and a reaction chamber 110 to control doses or pulses of the precursor from the accumulator 120.

The reactor system 100 may be utilized in high temperature applications in which the accumulator 120 and vessel 120 (and interconnection components) may contain and control flow of fluids such as precursor gases at temperatures over 100° C. or over 125° C. up to about 250° C. in some cases. In this regard, the valves of the reactor system 100 may be a digital valve, such as diaphragm valve, configured to operate in fully open or closed states or positions and are adapted to withstand these higher temperatures. Preferably, the valves may also be high-speed valves suited for the pulsing control described herein.

A pressure sensor 130, which may be a pressure transducer or the like, is provided to sense the pressure within the accumulator 120 and, based on the sensed pressure, to transmit pressure signals or readings (or pressure information) as shown at 131 (via wired or wireless communications) to the controller 160. The pressure sensor 130 is in fluid communication with the accumulator 120 as shown via valves 132 and 134 coupled to fill line 121 along with flow orifice 136 positioned between valve 134 and the accumulator 120. Valve 132 and/or valve 134 are opened during charging of the accumulator 120.

The reactor system 100 is well-suited for use with low-volatility precursors in vessel 140. In these cases, a carrier gas is used to assist in the charging of the accumulator 120 with precursor from vessel 140. As shown, a carrier gas source 150 is coupled to the vessel 140 and fill line 121 via line 151, valve 152, pressure flow controller 154 and valves 142, 158, and 159. A pressure sensor 156 is coupled to the carrier supply line 151 via valve 157.

Valves 142 and 144, as shown, act as precursor fill valves. Charging of the accumulator 120 occurs when these two valves 142 and 144 are opened to provide carrier gas to the vessel 140 and precursor to the accumulator 120 via fill line 121, with valve 128 remaining open during accumulator fill and reaction chamber pulsing operations. As discussed above, accumulator fill valves 142, 144 are preferably high-speed valves such as diaphragm valves adapted for rapid switching between fully open and fully closed and for use in high-temperature applications. A restrictor or orifice 146 may optionally be provided between the vessel outlet and the fill valve 144 to lower down or control flow to improve accuracy of precursor supply.

A controller 160 is included in the system 100 to control the pressure within the accumulator 120. The controller 160 may be any suitable electronic or computing device, such as a PLC, with a processor 162 executing instructions or code (e.g., software) to perform the functions of a pressure control module 180. In some arrangements, the pressure control module 180 takes the form of a PID control loop or algorithm that is configured to generate valve control or pulsing signals 181 and 183 to pulse the fill valves 142, 144 open and closed to control the pressure in the accumulator 120 by charging the accumulator with precursor from vessel 140. In some embodiments, valve pulsing is performed when the accumulator discharge valve 116 is closed or between dosing of precursor. In other embodiments, the valve pulsing is performed in continuous manner during a processing recipe by the reactor system 100 such that the pulsing may also be performed during precursor dosing, such as with valve 116 open.

The controller 160 includes input/output (I/O) 164 to receive the pressure signals 131 from the pressure sensor 130 and to also transmit the valve pulsing signals 181, 183 (in a wired or wireless manner) to the fill valves 142, 144. The controller 160 also includes (or has access to) memory or data storage 170. The processor 162 manages access to the memory 170 to store and retrieve for the pressure control module 180 the sensed accumulator pressure 172 and pressure control parameters 174, which may include any variables or settings used by the pressure control module 180 to generate the control signals 181, 183.

In practice, the pressure control module 180 takes as input the pressure set point 175 defining the desired pressure for the accumulator 120 for a particular substrate processing recipe as well as the pulse time interval or width (e.g., in the range of about 1 to 1000 ms or about 1 to 10 ms or about 1 to 20 ms or about 15 ms or the like) 176 and one or more user-defined PID variables 178 (when the pressure control module 180 takes the form of a PID control loop). In response to receipt of pressure signals or feedback 131 from the pressure sensor 130, the pressure control module 180 generates the valve pulsing signals 181, 183 to maintain the accumulator 120 at the pressure set point 175 (or about 0.1-0.2 Torr under the set point). The pressure control module 180 may, in some cases, be configured to shut off the valve pulsing operation when the accumulator 120 is discharging to the reaction chamber 110 (with valve 116 open), which may be useful to facilitate more accurate calculation of the dose of precursor provided with each pulse.

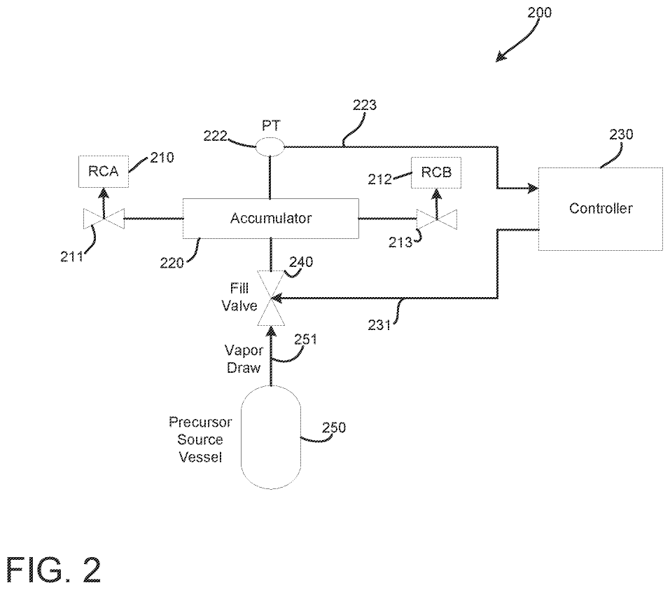

FIG. 2 illustrates an exemplary reactor system 200 that is useful with high volatility precursors (e.g., where high vapor pressure exists in the precursor source vessel) or systems in which a carrier gas is not utilized. The reactor system 200 includes an accumulator 220 downstream of a precursor source vessel 250, which is used to selectively charge the accumulator 220 via fill valve 240 as shown schematically with arrow 251 representing a vapor draw from the high volatility precursor in the vessel 250. Hence, the system 200 may be thought of as implementing a vapor draw method for charging the accumulator 220 with the precursor source vessel 250. This typically occurs between pulses or discharges from the accumulator 220 to one of two reaction chambers 210 and 212 via accumulator discharge valves 211 and 213, respectively.

As with the reactor system 100 of FIG. 1, the reactor system 200 includes a controller 230 that generates valve pulsing or control signals as shown with arrow 231 for the accumulator fill valve 240. The controller 230 may be configured similar to controller 160 in the reactor system 100 to include a pressure controller that uses a PID controller or control loop to generate the valve pulsing signals 231 based on a pressure set point for the accumulator 220 and the pressure of the accumulator (as well as a PID parameter that may be default or user defined). To this end, the reactor system 200 includes a pressure sensor 222 fluidly coupled to the accumulator 220 that senses the pressure of the accumulator 220 on an ongoing or continuous basis and, in response, transmits, as shown with arrow 223, pressure information to the controller 230 for processing with the pressure set point to generate the control signals 231 for fill valve 240.

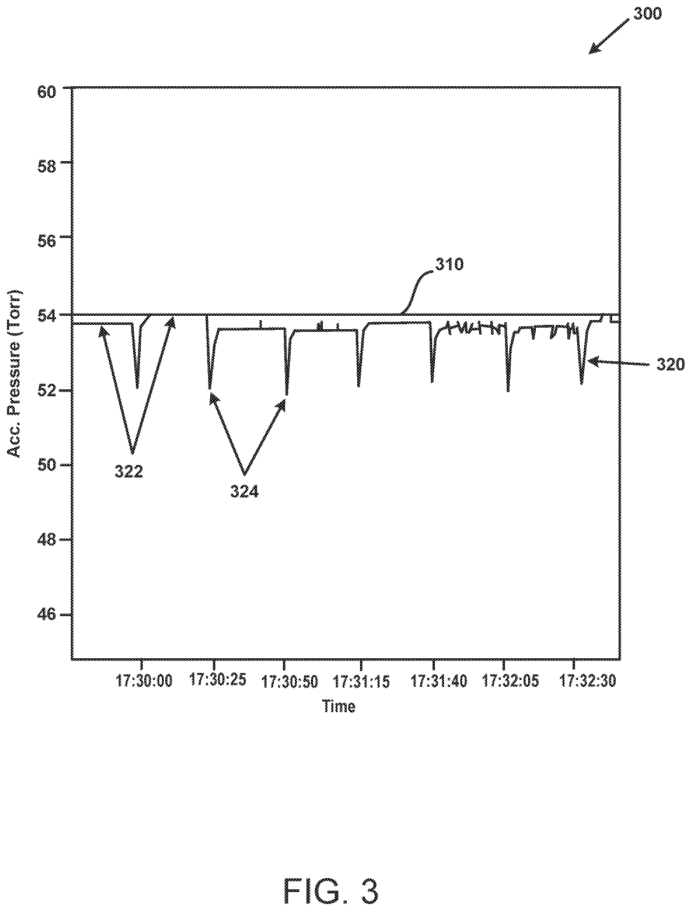

FIG. 3 is a graph 300 showing results of use of valve pulsing to provide accumulator pressure control such as during operations of the system 100 of FIG. 1 or the system 200 of FIG. 2. The graph 300 provides a plot of accumulator pressure 320 measured by a pressure sensor over time (e.g., over substrate processing steps). Line 310 illustrates a pressure set point of 54 Torr that was provided as input to a PLC running a PID control loop, and the PID control loop was further provided pressure feedback from the pressure sensor. Line 320 shows at 322 that valve pulsing is useful for providing accurate and consistent pressure control (or accumulator charging) in between dosing or when the accumulator is discharging into a reaction chamber as shown by dips or valleys 324 in the measured pressure 320.

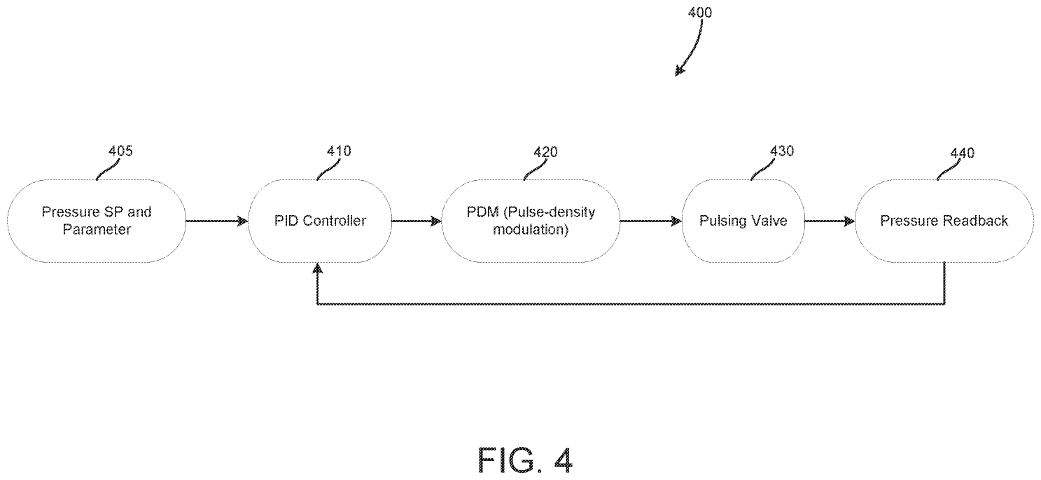

FIG. 4 illustrates a control flow chart or schematic for implementing a valve pulsing pressure control method 400, e.g., within system 100 or system 200. As shown, a PID controller or control module 410 takes as input 405 the pressure set point for the accumulator along with one or more parameters (e.g., a user-defined PID parameter). As further input, the PID controller 410 receives, from a pressure sensor fluidly communicating with the accumulator, a pressure readback or signal 440 corresponding to a current pressure of the precursor gas within the accumulator. The PID controller 410 processes these inputs at 420 to perform pulse-density modulation (PDM) to generate valve control signals that causes, as shown at 430, the accumulator fill valve (or valves) to pulse (at a predefined pulsing interval) between fully open and fully closed, thereby charging the accumulator with additional precursor to control the accumulator pressure at or near the pressure set point.

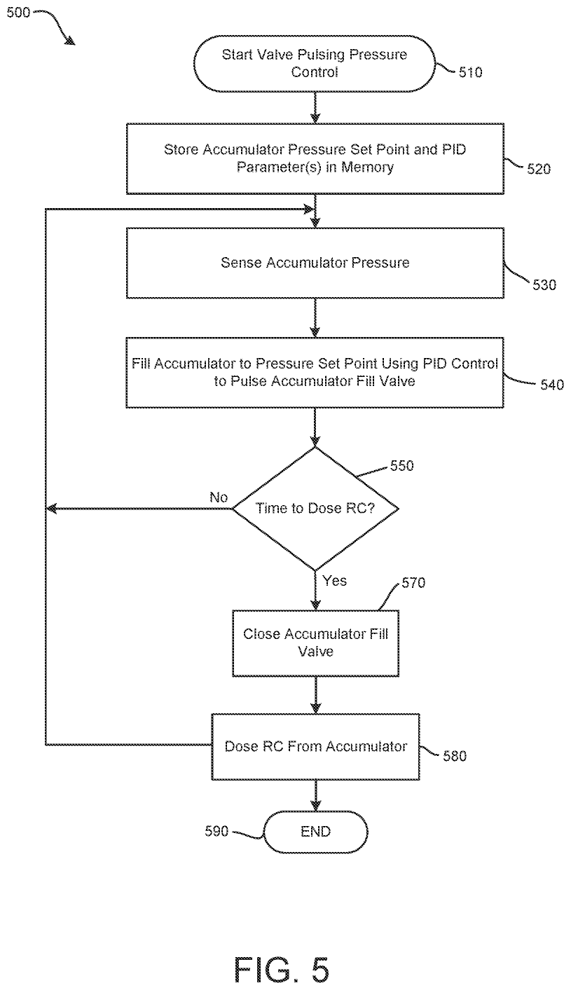

FIG. 5 illustrates a flow diagram for a pulsing valve method 500 of controlling accumulator pressure in a reactor system. The method 500 may be implemented by operations, for example, of the systems 100 and 200 of FIGS. 1 and 2, respectively, and the method 500 starts at 510 such as with providing a pressure sensor on or associated with the accumulator and modifying a fill valve controller to be configured to run a PID control loop, which may include a subroutine to perform pulse-width modulation, to generate valve pulsing control signals for the fill valve(s) of the accumulator.

The method 500 continues at 520 with storing an accumulator pressure set point(s) and one or more PID parameters in memory or data storage accessible by the valve controller. Then, at 530, the method 500 includes sensing the accumulator pressure and, in response, transmitting pressure signals or information from the pressure sensor to the controller. At 540, the method 500 continues with filling or charging the accumulator with precursor from the precursor source vessel to obtain an accumulator pressure at or near the pressure set point. The PID control loop takes as input the pressure set point, the PID parameter(s), and the accumulator pressure feedback and generates control signals that cause the fill valve(s) to pulse rapidly between a fully closed position to a fully open position over time (e.g., to simulate a partially open valve).

Then, at 550, the method 500 includes the controller determining whether it is time in the substrate processing recipe to dose the reaction chamber fed by the accumulator with precursor. If not, the method 500 continues with repeating steps 530 and 540. If yes, the method 500 continues at 570 with closing the accumulator fill valve (e.g., halting or pausing the pulsing of the fill valve). Then, at 580, the method 500 continues with dosing the reaction chamber with precursor from the charged/pressurized accumulator. The method 500 may then continue with repeating steps 530 and 540 or may end as shown at 590.

Although exemplary embodiments of the present disclosure are set forth herein, it should be appreciated that the disclosure is not so limited. For example, substrate handler devices having one or more adjustable joints are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

We claim:

1. A method of controlling precursor pressure in a reactor system, comprising:
in data storage, storing a pressure set point for an accumulator adapted for storing precursor and for discharging the precursor to a reaction chamber during substrate processing;
with a pressure sensor, sensing a pressure within the accumulator and, in response, generating a signal indicative of the pressure;
with a controller, processing the signal from the pressure sensor and the pressure set point; and
based on the processing, generating a control signal for a fill valve operable to charge the accumulator with the precursor from a volume of the precursor stored in a precursor source vessel,
wherein the control signal causes the fill valve to pulse repeatedly between a closed position and an open position during the substrate processing.

2. The method of claim 1, wherein the processing comprises a proportional-integral-derivative (PID) control loop taking as input the pressure set point, a user-defined PID parameter, and the signal from the pressure sensor and producing an output.

3. The method of claim 2, wherein the generating of the control signal comprises performing pulse-density modulation (PDM) on the output of the PID control loop.

4. The method of claim 1, further comprising determining that the accumulator is discharging the precursor to the reaction chamber and, in response, pausing the generating of the control signal for the fill valve.

5. The method of claim 1, wherein the precursor passing through the fill valve is at temperatures over 100° C.

6. The method of claim 5, wherein the fill valve is a high-speed valve operable only in a fully open position or a fully closed position.

7. The method of claim 6, wherein the high-speed valve is a diaphragm valve.

8. The method of claim 1, wherein the control signal causes the fill valve to have a pulse time interval in the range of 1 to 1000 milliseconds (ms).

9. The method of claim 1, further comprising, concurrently with the generating the control signal for the fill valve, generating a second control signal for a valve operable to control flow of a carrier gas from a carrier gas source through the precursor source vessel, wherein the control signal causes the fill valve to pulse repeatedly between a closed position and an open position in a pattern matching that of the fill valve operating in response to the control signal.

10. A method of controlling precursor pressure in a reactor system, comprising:
in data storage, storing a pressure set point for an accumulator adapted for storing precursor and for discharging the precursor to a reaction chamber;
sensing a pressure in the accumulator;
with a PID control loop, processing the sensed pressure in the accumulator along with the pressure set point; and
based on the processing, pulsing a fill valve over a charging time period to charge the accumulator, the fill valve being disposed between a source vessel for the precursor and the accumulator,
wherein the fill valve is operable to switch between a fully open position and a fully closed position during the pulsing.

11. The method of claim 10, wherein the charging time period coincides with a time period between dosing the precursor from the accumulator to a reaction chamber and wherein the fill valve is closed during the dosing.

12. The method of claim 10, wherein the pulsing comprises generating a control signal for the fill valve by performing pulse-density modulation (PDM) on an output of the PID control loop.

13. The method of claim 12, wherein the control signal causes the fill valve to have a pulse time interval in the range of 1 to 1000 milliseconds (ms).

14. The method of claim 10, wherein the fill valve is rated for fluid temperatures over 100° C. and wherein the fill valve is a high-speed diaphragm valve operable only in a fully open position or a fully closed position.

15. A reactor system adapted for enhanced accumulator pressure control, comprising:
a reaction chamber;
an accumulator fluidly coupled to the reaction chamber;
a precursor source vessel storing a precursor, wherein the precursor source vessel is fluidly coupled to the accumulator via a fill line;
a pressure sensor operable to sense a pressure within the accumulator and generate a signal indicative of the pressure;
a controller configured to:
process the signal from the pressure sensor along with a pressure set point for the accumulator;
generate a control signal according to the sensed pressure; and
transmit the control signal; and
a fill valve disposed in the fill line, wherein the fill valve receives the control signal from the controller and pulses between a closed position and an open position to charge the accumulator with the precursor based on the control signal.

16. The reactor system of claim 15, wherein the controller comprises a processor configured to receive the pressure set point, a PID parameter, and the signal indicative of the pressure of the accumulator sensed by the pressure sensor, execute a PID control loop based on the pressure set point, a PID parameter, and the signal indicative of the pressure of the accumulator sensed by the pressure sensor, generate a PID output signal according to the executed PID control loop, and generate the control signal based on the PID output signal.

17. The reactor system of claim 16, wherein the processor is further configured to modulate the PID output signal and generate the control signal according to the modulated PID output signal.

18. The reactor system of claim 15, wherein the fill valve is a high-speed diaphragm rated for operation at temperatures over 100° C.

19. The reactor system of claim 15, wherein the control signal causes the fill valve to have a pulse time interval in the range of 1 to 1000 milliseconds (ms).

20. The reactor system of claim 15, wherein the controller is configured to generate the control signal during time periods between dosing of the precursor from the accumulator and the reaction chamber and to close the fill valve during the dosing.
